(19) United States
(12) Patent Application Publication
(10) Pub. No.: US 2001/0016024 A1
(43) Pub. Date: Aug. 23, 2001

(54) Configuration and method for clock regeneration

(76) Inventor: Thomas Treyer, Munchen (DE)

Correspondence Address: LERNER AND GREENBERG, P.A., Post Office Box 2480, Hollywood, FL, 33022-2480, US

(21) Appl. No.: 09/771,453

(22) Filed: Jan. 26, 2001

(30) Foreign Application Priority Data
Jan. 26, 2000 (DE) 100 03 258.3

(51) Int. Cl. H03D 3/24

(52) U.S. Cl. 375/373

(57) ABSTRACT

A configuration for clock regeneration includes a frequency measuring device having an input for receiving a reference frequency signal. A digital signal processing device is connected to the frequency measuring device. A numerically controlled oscillator is connected to the digital signal processing device. A clock device supplies a local clock signal to the frequency measuring device and to the numerically controlled oscillator. The configuration for clock regeneration can be implemented in all-digital form and has no feedback control loop, requires no locking process, has no increased jitter in the jitter transfer function and allows fast frequency hopping. A method for clock regeneration is also provided.

### BACKGROUND OF THE INVENTION

1. Field of the Invention:

The invention is in the field of digital frequency retuning and relates in particular to a configuration and a method for clock regeneration.

A clock regeneration is part of many electronic circuits. Clock regeneration picks up an existing reference clock and derives a higher-quality output clock therefrom. Depending on the respective application, a distinction must be made between the following clock processing operations:

The output clock has less jitter than the reference clock.

The output clock has a defined phase in relation to the reference clock.

The output clock has a higher or lower frequency than the reference clock.

The output clock has a frequency modulation or phase modulation which the reference clock does not have (e.g. frequency hopping).

In most cases, a Phase Locked Loop (PLL) or Delay Locked Loop (DLL) is used as a control circuit in order to implement a clock regenerator. The feedback present in these devices is disadvantageous for some applications that use a clock regenerator.

### SUMMARY OF THE INVENTION

It is accordingly an object of the invention to provide a method and a configuration for clock regeneration which overcome the above-mentioned disadvantages of the heretofore-known methods and configurations of this general type and which avoid the disadvantages associated with feedback.

With the foregoing and other objects in view there is provided, in accordance with the invention, a configuration for clock regeneration, including:

a frequency measuring device having an input for receiving a reference frequency signal;

a digital signal processing device connected to the frequency measuring device;

a numerically controlled oscillator connected to the digital signal processing device; and

a clock device for supplying a local clock signal to the frequency measuring device and to the numerically controlled oscillator.

Advantages of this clock regeneration configuration result directly from the fact that the configuration according to the invention, which forms a digital phase amplifier DPA, is not a feedback control loop, but corresponds to a straight-through amplifier or straight-forward amplifier. These advantages are in particular that there is no jitter increase in the jitter transfer function, that no lock process is required, and that a fast frequency hopping is possible.

In addition, the DPA (Digital Phase Amplifier) offers the advantage that it can be implemented in an all-digital form and requires no analog components. This results in advantages with regard to cost and space requirements.

With the objects of the invention in view there is also provided, a method for clock regeneration, which includes the steps of:

feeding a reference clock to a frequency measuring device;

recording a reference frequency of the reference clock at equidistant time intervals as sample values;

supplying the sample values to a digital signal processing device;

producing a first output frequency by digitally processing the sample values in the digital signal processing device;

supplying, with the digital signal processing device, the first output frequency to a numerically controlled oscillator;

supplying a second output frequency with the numerically controlled oscillator controlled by the first output frequency;

providing, with a clock device, a local clock signal to the frequency measuring device for deriving a sampling time for recording the sample values; and

supplying, with the clock device, the local clock signal to the numerically controlled oscillator as a time basis for deriving the second output frequency.

According to another mode of the invention, a signal edge of the local clock signal which is closest to a calculated signal edge is supplied as a signal edge of the second output frequency.

According to yet another mode of the invention, a deviation or difference between the calculated signal edge and the signal edge of the local clock signal which is closest to the calculated signal edge is recorded and is stored in an error memory.

According to a further mode of the invention, the deviations are added up for a plurality of signal edges.

According to another mode of the invention, the added up deviations are taken into account when calculating the calculated signal edge.

Other features which are considered as characteristic for the invention are set forth in the appended claims.

Although the invention is illustrated and described herein as embodied in a digital phase amplifier, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a block diagram of a configuration for clock regeneration according to the invention; and

FIG. 2 is a flow chart illustrating processes in the configuration for clock regeneration of FIG. 1.

### DESCRIPTION OF THE PREFERRED EMBODIMENTS

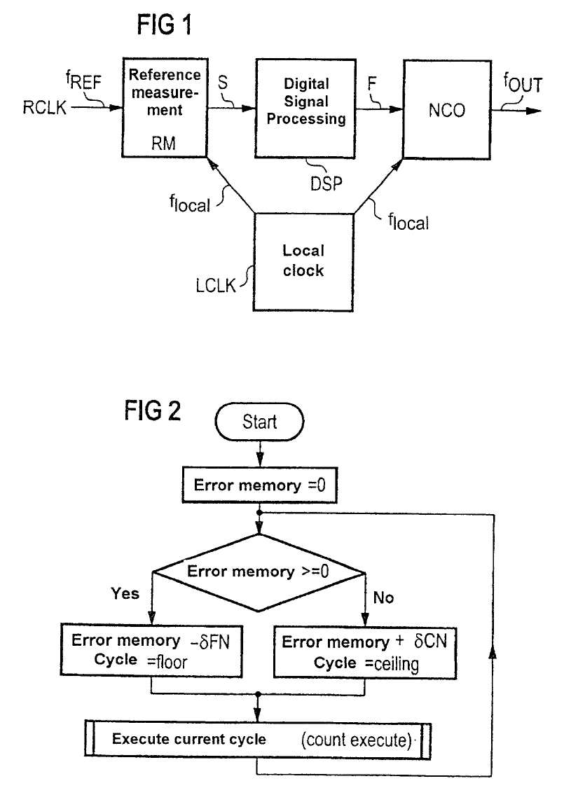

Referring now to the figures of the drawings in detail and first, particularly, to FIG. 1 thereof, there is shown a configuration for clock regeneration or phase amplifier, in which a reference frequency signal RCLK (Reference Clock) with the reference frequency f_{REF} and a local clock signal with the local frequency f_{local} are fed on the input side to a frequency measuring device RM (Reference Measuring). The frequency measuring device feeds measurement values S (Sample) to a digital signal processing device DSP. A desired frequency or set frequency F from the digital signal processing device and the local clock signal with the local frequency f_{local} are fed to a numerically controlled oscillator NCO.

The configuration according to the invention, which is also referred to as a digital phase amplifier DPA, processes the reference clock in three stages:

Stage 1: Measurement of the reference frequency at equidistant time intervals.

Stage 2: Digital signal processing, e.g. averaging of the measurement values in order to attain the desired PLL bandwidth.

Stage 3: Output of the result with the aid of a numerically controlled oscillator (NCO).

It is important for the correct function of the DPA that the sampling time or gate time of the reference measurement is derived from the same clock source as the time basis of the NCO, so that the inevitable errors of the reference measurement are correlated with the frequency error of the NCO.

The DPA operation is all-digital, i.e. digital samples are transmitted at equidistant time intervals between the processing stages.

In stage 2, the current mean value can be manipulated as required with the aid of digital signal processing in order to carry out one of the following functions:

a) Frequency modulation or phase modulation

b) Frequency hopping (in contrast to a feedback control circuit (e.g. PLL), the output clock can abruptly change its frequency)

c) Frequency conversion, wherein any required rational number is permitted as a conversion factor. In contrast to a feedback control circuit (e.g. PLL), this conversion factor is independent of the nominal values of the input and output frequency and the PLL bandwidth.

Measuring the Reference Frequency

A counter counts the edges of the reference. At equidistant time intervals δt, the counter reading is taken and the sample value S is transmitted for downstream averaging. The following boundary conditions or constraints apply:

a) The counter is not reset when the counter reading is taken.

b) The equidistant time intervals δt are generated by the same local time basis which, in the third processing stage, is also the time basis for the NCO.

c) The counter is dimensioned with a sufficient capacity such that no more than one counter overflow takes place within the sampling interval in processing stage 2.

Averaging of the Measurement Values

In many applications, a clock regenerator is expected to dampen high-frequency jitter. This low-pass function is most simply implemented with the averaging described here.

The low-pass function is based on a floating averaging. To do this, n+1 values are stored in a FIFO (First In First Out Storage). The integer value n is determined by the required PLL (Phase Locked Loop) bandwidth, which is determined by the cutoff frequency f_{3dB} and is calculated according to the following formula:

$$n = \frac{1}{π \cdot δ t \cdot {f}_{3 dB}} \qquad ( 1 )$$

In order to define the mean value M, the first and the last values FIFO[0] and FIFO[n] respectively in the FIFO are subtracted and the difference thus obtained is divided by n.

$$M = \frac{FIFO [ 0 ] - FIFO [ n ]}{n \cdot δ t} \qquad ( 2 )$$

Frequency Conversion

This stage is required only if the frequency F which is to be output has a value other than the reference or if the frequency which is to be output is to be modulated. To do this, the mean value M is multiplied by a rational number, i.e. by a fraction of integer numbers k₁ and k₂.

$$F = M \cdot \frac{{k}_{1}}{{k}_{2}} = \frac{( FIFO [ 0 ] - FIFO [ n ] ) \cdot {k}_{1}}{n \cdot δ t \cdot {k}_{2}} \qquad ( 3 )$$

In the case of frequency modulation, the numbers k₁ and k₂ are modified in a desired manner from one time interval to the next.

Numerically Controlled Oscillator:

The input parameter of the NCO (Numerically Controlled Oscillator) is the desired frequency or set frequency F, represented as a rational number, i.e. as a fraction of integer numbers. The NCO thus has two integers as input parameters, i.e. the denominator and the numerator of equation (3).

The NCO is an all-digital circuit which operates synchronously with a local clock. This local clock frequency f_{local} of the NCO must be at least as high as the output frequency.

Overview of the Calculation

The NCO begins with the first output edge and then continuously performs a calculation in order to determine the time at which the next edge of the output signal must be generated. This calculation is performed in multiples of the cycle duration of the local clock and in turn supplies a rational number. The NCO must then round this number to the nearest edge of the local clock.

This rounding error necessarily results in jitter. To prevent the rounding error from resulting in a frequency deviation of the output, the rounding error of each calculation is registered in an error memory and is also processed in the next calculation.

Calculation in Detail

On average, the NCO must wait for PZ cycles or periods of the local clock before it must output the next edge. PZ is the quotient from the local frequency f_{local} and the desired frequency F.

$$PZ = \frac{{f}_{local}}{F} = \frac{n \cdot δ t \cdot {k}_{2} \cdot {f}_{local}}{( FIFO [ 0 ] - FIFO [ n ] ) \cdot {k}_{1}} \qquad ( 4 )$$

The numbers floor, ceiling, δF and δC are formed from PZ in the next stage, wherein:

floor: next smaller integer of PZ

ceiling: next higher integer of PZ

δF=PZ - floor

δC=ceiling - PZ

The following initially applies: ceiling=floor+1

Floor and ceiling limit the minimum and maximum frequency values which the NCO can supply. In most applications, no wide NCO pull-in range is required. However, if a wider pull-in range is required, the floor must be reduced and the ceiling increased.

δF and δC are initially rational numbers, but both have the same denominator. Extension with this denominator produces the following integer numbers for δFN and δCN:

δFN=(PZ - floor)* denominator(PZ)=(n·δt·k₂·f_{local}) - floor k₁·(FIFO[0] - FIFO[n]) (5)

δFC=(ceiling - PZ)* denominator(PZ)=ceiling·k₁·(FIFO[0] - FIFO[n]) - (n·δt ·k₂·f_{local}) (6)

The values for δFN and δFC are calculated once for each sample interval δT. If these values are present, they are processed by the NCO (see FIG. 2).

FIG. 2 illustrates how deviations or differences between a calculated signal edge and the signal edge of the local clock signal closest to the calculated signal edge are registered, stored and processed using an error memory. Starting out with a value of zero in the error memory, this value may be changed when a difference between the calculated signal edge and the signal edge of the local clock signal closest to the calculated signal edge is stored. Depending on whether the value in the error memory is higher than zero, the error memory value is modified and the period is set to floor and ceiling respectively. Subsequently the current period is executed.

In the reference measurement method described here, it may become disadvantageously noticeable that the measurement value is affected by jitter, the peak-to-peak value of which corresponds to the cycle duration of the reference frequency. This jitter can be reduced if not only the number of reference cycles or reference periods is recorded, but also the time duration of the interval from the last edge of the reference to the end of the sampling time. This interpolation value can be recorded in an analog manner, although digital interpolation with the time resolution of the local clock is also possible.

I claim:

1. A configuration for clock regeneration, comprising:
a frequency measuring device having an input for receiving a reference frequency signal;
a digital signal processing device connected to said frequency measuring device;
a numerically controlled oscillator connected to said digital signal processing device; and
a clock device for supplying a local clock signal to said frequency measuring device and to said numerically controlled oscillator.

2. A method for clock regeneration, the method which comprises:
feeding a reference clock to a frequency measuring device;
recording a reference frequency of the reference clock at equidistant time intervals as sample values;
supplying the sample values to a digital signal processing device;
producing a first output frequency by digitally processing the sample values in the digital signal processing device;
supplying, with the digital signal processing device, the first output frequency to a numerically controlled oscillator;
supplying a second output frequency with the numerically controlled oscillator controlled by the first output frequency;
providing, with a clock device, a local clock signal to the frequency measuring device for deriving a sampling time for recording the sample values; and
supplying, with the clock device, the local clock signal to the numerically controlled oscillator as a time basis for deriving the second output frequency.

3. The method according to claim 2, which comprises supplying, as a signal edge of the second output frequency, a signal edge of the local clock signal closest to a calculated signal edge.

4. The method according to claim 3, which comprises recording and storing, in an error memory, a deviation between the calculated signal edge and the signal edge of the local clock signal closest to the calculated signal edge.

5. The method according to claim 4, which comprises adding up the deviation between the calculated signal edge and the signal edge of the local clock signal closest to the calculated signal edge for a plurality of signal edges.

6. The method according to claim 5, which comprises taking added up deviations between the calculated signal edge and the signal edge of the local clock signal closest to the calculated signal edge into account when calculating the calculated signal edge.
